(19) United States
(12) Patent Application Publication
(10) Pub. No.: US 2012/0175581 A1
(43) Pub. Date: Jul. 12, 2012

(54) SWITCHING DEVICE AND SEMICONDUCTOR MEMORY DEVICE INCLUDING THE SAME

(76) Inventor: Sang-Min HWANG, Gyeonggi-do (KR)

(21) Appl. No.: 13/333,937

(22) Filed: Dec. 21, 2011

(30) Foreign Application Priority Data
Jan. 6, 2011 (KR) 10-2011-0001321

(51) Int. Cl. H01L 47/00; H01L 29/861; H01L 29/82

(52) U.S. Cl. 257/2; 257/421; 257/734; 257/43; 257/E29.327; 257/E29.323; 257/E47.001

(57) ABSTRACT

A semiconductor memory device using a diode as a switching device is disclosed. The switching device may enhance on and off characteristics at the same time. The switching device includes a diode including a first conductive layer and a second conductive layer stacked therein, where the first conductive layer and the second conductive layer have complementary conductive types to each other, a control electrode surrounding the first conductive layer, and an insulation layer disposed between the first conductive layer and the control electrode.

### CROSS-REFERENCE TO RELATED APPLICATIONS

The present application claims priority of Korean Patent Application No. 10-2011-0001321, filed on Jan. 6, 2011, which is incorporated herein by reference in its entirety.

### BACKGROUND

1. Field

Exemplary embodiments of the present invention relate to a semiconductor device fabrication technology, and more particularly, to a semiconductor memory device using a diode as a switching device.

2. Description of the Related Art

A semiconductor memory device using resistance variation has been developed as a next-generation memory device, which may replace Dynamic Random Access Memory (DRAM) devices and flash memory devices. Generally, such a semiconductor memory device includes a plurality of unit cells, each of which has a switching device for selecting a corresponding cell and a variable resistor that is electrically connected to the switching device and has a variable resistance. Here, a diode may be used as the switching device to realize high integration of a semiconductor memory device.

FIG. 1 is a circuit diagram illustrating a conventional semiconductor memory device.

Referring to FIG. 1, the conventional semiconductor memory device includes a plurality of word lines WL and a plurality of bit lines BL. The word lines WL and the bit lines BL cross each other and a memory cell MC including a diode 12 and a variable resistor 11 that are disposed serially is formed at a cross point (intersection) of a word line WL and a bit line BL.

The diode 12 is to have excellent on/off characteristics in order to secure excellent operation characteristics of the semiconductor memory device having the above-described structure, such as read and write operation characteristics. In short, the diode 12 is to have great amount of on-current while having a small amount of off-current.

However, since the amount of on-current and the amount of off-current in the diode 12 are in a trade-off relationship, it is difficult to simultaneously increase the on-current while minimizing the off-current.

### SUMMARY

An embodiment of the present invention is directed to a switching device that may enhance on and off characteristics thereof at the same time.

Another embodiment of the present invention is directed to a semiconductor memory device that may have enhanced read operation characteristics and write operation characteristics.

In accordance with an embodiment of the present invention, a switching device includes: a diode including a first conductive layer and a second conductive layer stacked therein, where the first conductive layer and the second conductive layer have complementary conductive types to each other; a control electrode surrounding the first conductive layer; and an insulation layer disposed between the first conductive layer and the control electrode.

In accordance with another embodiment of the present invention, a semiconductor memory device includes: a plurality of word lines; a plurality of bit lines crossing over the word lines; and memory cells disposed at intersections of the word lines and the bit lines and including a switching device and a variable resistor that are serially coupled, wherein the switching device includes: a first conductive layer; a second conductive layer, where the first conductive layer and the second conductive layer are sequentially stacked and have complementary conductive types to each other; and a control electrode surrounding the first conductive layer.

In accordance with yet another embodiment of the present invention, a semiconductor memory device includes: a plurality of sub-word lines formed over a substrate; a first conductive layer and a second conductive layer sequentially stacked over the sub-word lines, where the first conductive layer and the second conductive layer have complementary conductive type to each other; a control line formed over the sub-word lines and surrounding the first conductive layer; an insulation layer interposed between the first conductive layer and the control line; a variable resistor formed over the second conductive layer; and a plurality of bit lines formed over the variable resistor and crossing over the sub-word lines.

The semiconductor memory device may further include: main word lines crossing over the bit lines and electrically connected to the sub-word lines and the control line.

### BRIEF DESCRIPTION OF THE DRAWINGS

FIG. 1 is a circuit diagram illustrating a conventional semiconductor memory device.

FIGS. 2 to 5 illustrate a semiconductor memory device in accordance with an embodiment of the present invention.

FIGS. 6A to 6D are cross-sectional views illustrating a variable resistor that may be applied to a semiconductor memory device in accordance with an embodiment of the present invention.

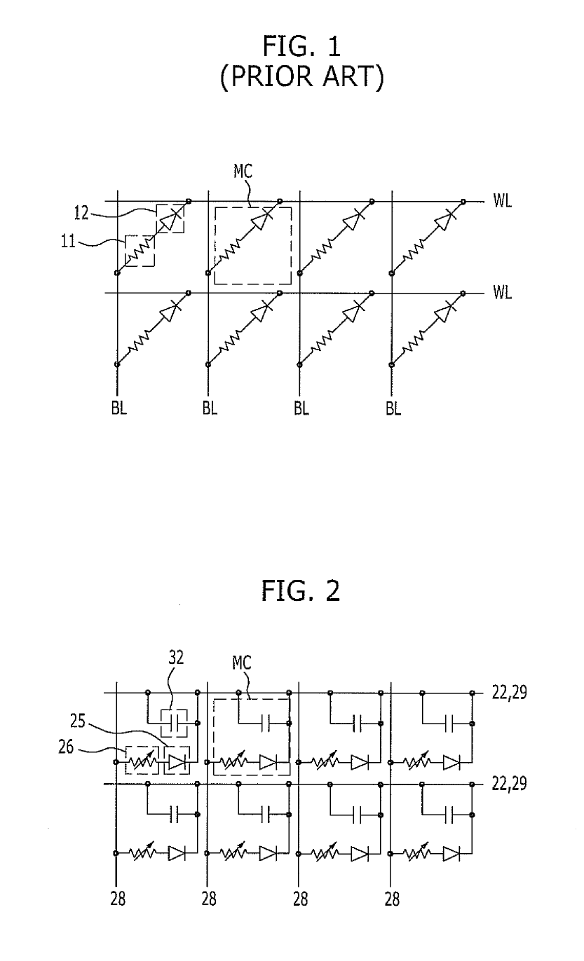

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

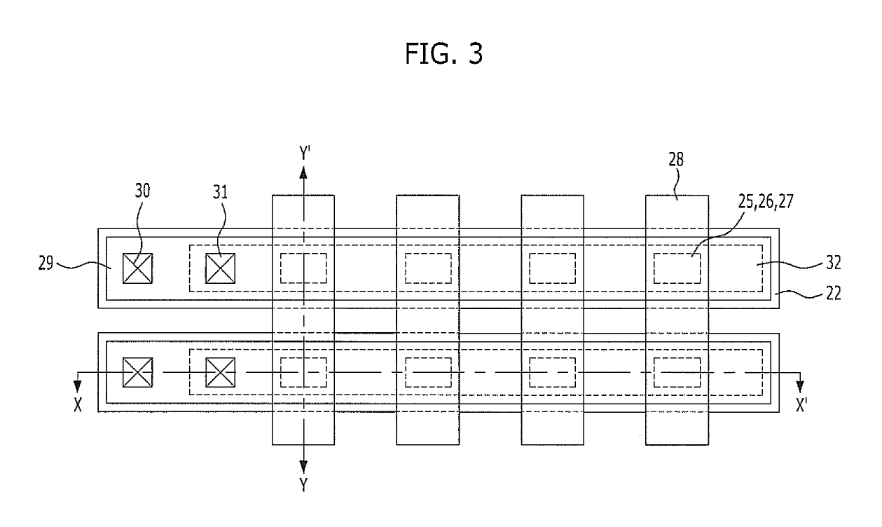

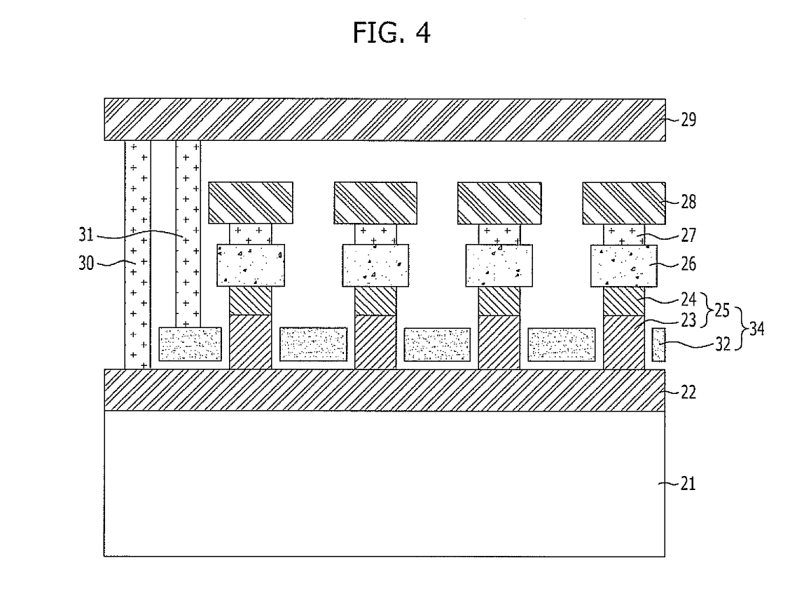

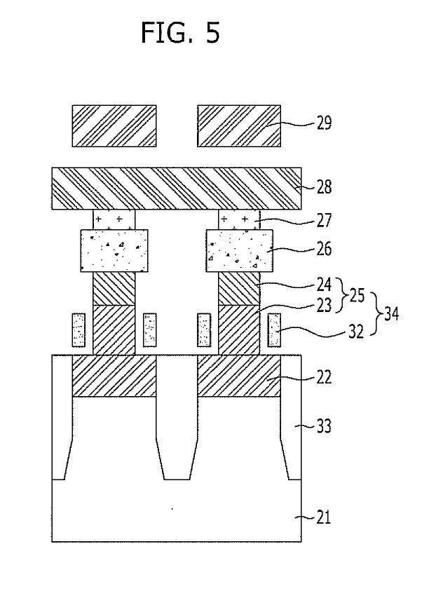

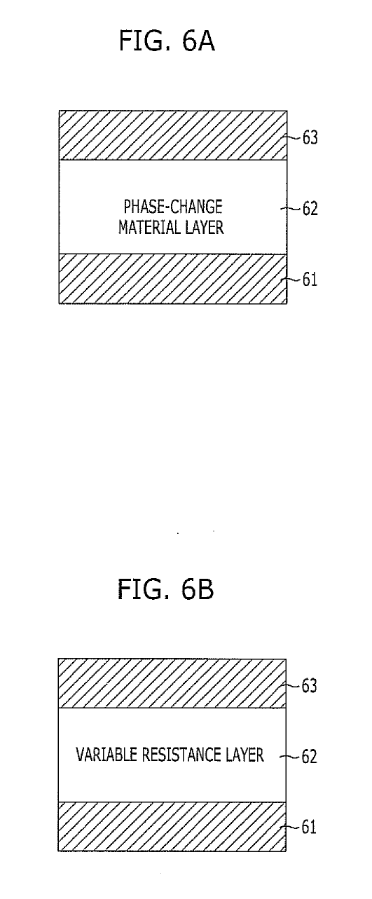

FIGS. 2 to 5 illustrate a semiconductor memory device in accordance with an embodiment of the present invention. FIG. 2 is a circuit diagram and FIG. 3 is a plan view. FIG. 4 is a cross-sectional view taken along an X-X′ line that is shown in FIG. 3. FIG. 5 is a cross-sectional view taken along a Y-Y′ line that is shown in FIG. 3.

Referring to FIGS. 2 to 5, the semiconductor memory device in accordance with an embodiment of the present invention includes a plurality of word lines 22 and 29, a plurality of bit lines 28 crossing over the word lines 22 and 29, and memory cells MC that are disposed at the cross points where the word lines 22 and 29 and the bit lines 28 are crossed.

The word lines 22 and 29 include sub-word lines 22 and main word lines 29. The sub-word lines 22 and the main word lines 29 are electrically connected to each other through second plugs 30. The sub-word lines 22 and the main word lines 29 are formed as line patterns that are stretched in the same direction. The sub-word lines 22 and the main word lines 29 have an overlapping structure to increase the integration degree of a semiconductor memory device. The sub-word lines 22 may be impurity regions formed over a substrate 21, and adjacent sub-word lines 22 are electrically isolated from each other by an isolation layer 33. The main word lines 29 may be formed over the substrate 21 as metal lines, and the main word lines 29 may be coupled with a plurality of sub-word lines 22 through the second plugs 30. For example, when the sub-word lines 22 are disposed on the basis of mat, the main word lines 29 may be disposed on the basis of bank.

The bit lines 28 may be lines formed over the substrate 21, such as metal lines, and the bit lines 28 may be disposed between the sub-word lines 22 and the main word lines 29.

The memory cells MC are disposed at the cross points where the sub-word lines 22 and the bit lines 28 are crossed by each other. Each memory cell MC includes a switching device 34 and a variable resistor 26. The memory cells MC have a structure where the switching device 34 and the variable resistor 26 are sequentially stacked, that is, a structure where the switching device 34 and the variable resistor 26 are serially coupled. Here, the switching device 34 may be coupled with a sub-word line 22, and the variable resistor 26 may be coupled with a bit line 28 through a first plug 27.

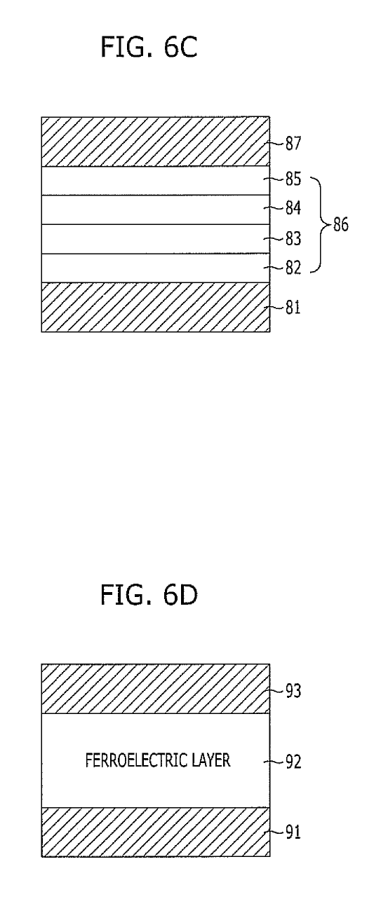

The variable resistors 26 may be any devices that may have at least two resistance states in response to a bias voltage that is applied through the word lines 22 and 29 and the bit lines 28. The variable resistor 26 in accordance with the embodiment of the present invention will be described below with reference to FIGS. 6A to 6D.

The switching device 34 includes a diode 25 and a control electrode 32. The diode 25 includes a first conductive layer 23 of a first conductive type and a second conductive layer 24 of a second conductive type that are sequentially stacked. Here, the first conductive type and the second conductive type are in a complementary relationship, that is, they may be opposite types in the polarity to each other. The first conductive layer 23 and the second conductive layer 24 are electrically isolated from the control electrode 32 by an insulation layer (not shown) interposed therebetween. For example, the first conductive type may be an N type, while the second conductive type is a P type, and the diode 25 may be a PN diode.

The first conductive layer 23 and the second conductive layer that constitute the diode 25 may include a compound semiconductor including silicon, germanium, and silicon or a compound semiconductor including germanium. The first conductive layer 23 and the second conductive layer 24 may be formed by doping the compound semiconductor including silicon, germanium, and silicon or a compound semiconductor including germanium with impurity. Also, the first conductive layer 23 and the second conductive layer 24 may include an oxide having semiconductor characteristics. For example, nickel oxide (NiO) and copper oxide (CuO) may be used as the oxide having P-type semiconductor characteristics, and titanium oxide (TIO), zirconium oxide (ZnO), and indium zirconium oxide (InZnO) may be used as the oxide having N-type semiconductor characteristics.

The control electrode 32 may have a structure of surrounding a part of the first conductive layer 23 or the entire first conductive layer 23. The control electrode 32 may be a line pattern that is stretched in the same direction as the word lines 22 and 29. The control electrode 32 and the word lines 22 and 29 have an overlapping structure to increase the integration degree of a semiconductor memory device. The control electrode 32 is electrically coupled with the main word line 29 through a third plug 31. Therefore, the same bias voltage is applied to the control electrode 32 as the word lines 22 and 29. In short, the same bias voltage is applied to the control electrode 32 as the first conductive layer 23. Here, the control electrode 32 may be disposed on the basis of mat, just as the sub-word lines 22 are disposed, and a plurality of control electrodes 32 may have a structure where they are coupled with the main word lines 29 through the third plugs 31.

The first conductive layer 23 of the diode 25 may have contact with the sub-word lines 22 and the second conductive layer 24 of the diode 25 may have contact with the variable resistors 26. The conductive type of the sub-word lines 22 formed of an impurity region over the substrate 21 is the same as the conductive type of the first conductive layer 23. In other words, when the conductive type of the first conductive layer 23 is an N type, the conductive type of the sub-word lines 22 is an N type. Here, the impurity doping concentration of the impurity region that forms the sub-word lines 22 may be higher than the impurity doping concentration of the first conductive layer 23 in order to enhance the on-current, or on-operation characteristics, of the diode 25.

Hereafter, the operation of the semiconductor memory device having the above-described structure is described in detail. Hereafter, a case where the conductive type of the first conductive layer 23 surrounded by the control electrode 32 is an N type is exemplarily described.

When a first voltage is applied to the bit lines 28 and a second voltage, which is lower than the first voltage, is applied to the main word lines 29, current flows in a forward direction in the diode 25 due to the voltage difference between the bit lines 28 and the main word lines 29. In short, the diode 25 is turned on. Here, the second voltage is applied to the control electrode 32 and the sub-word lines 22 coupled with the main word lines 29. As the same low voltage is applied to the control electrode 32 surrounding the first conductive layer 23 as the word lines 22 and 29, the inside of the first conductive layer 23 comes to be in an accumulation state, thereby increasing the on-current of the diode 25.

Conversely, when a low voltage is applied to the bit lines 28 and a high voltage is applied to the main word lines 29, current flows in a reverse direction in the diode 25 due to the voltage difference between the bit lines 28 and the main word lines 29. In short, the diode 25 is turned off. Here, the high voltage is applied to the control electrode 32 and the sub-word lines 22 coupled with the main word lines 29. As the same high voltage is applied to the control electrode 32 surrounding the first conductive layer 23 as the word lines 22 and 29, the inside of the first conductive layer 23 comes to be in a depletion state or inversion state, thereby decreasing the off-current of the diode 25. In short, as the depletion area of the first conductive layer 23 is extended, the reverse saturation current of the diode 25 is reduced.

In another embodiment, it is assumed that the conductive type of the first conductive layer 23 is a P type. In this case, when the second voltage is applied to the bit lines 28 and the first voltage, which is higher than the second voltage, is applied to the main word lines 29, current flows in a forward direction in the diode 25 due to the voltage difference between the bit lines 28 and the main word lines 29. In short, the diode 25 is turned on. Conversely, when a high voltage is applied to the bit lines 28 and a low voltage is applied to the main word lines 29, current flows in a reverse direction in the diode 25 due to the voltage difference between the bit lines 28 and the main word lines 29. In short, the diode 25 is turned off. Accordingly, the same operation may be performed.

As described above, since the semiconductor memory device in accordance with the embodiment of the present invention includes the control electrode 32, the on-current of the diode 25 is increased while reducing off-current at the same time. Therefore, the on/off characteristics of the switching device 34 may be enhanced simultaneously and the operation characteristics of the semiconductor memory device including the switching device 34 may be enhanced.

Also, since the control electrode 32 is coupled with the main word line 29, the semiconductor device may not include an additional unit for controlling the level of the bias voltage applied to the control electrode 32. Therefore, the integration degree of the semiconductor memory device may be increased.

Further, in another embodiment, the bit lines 28 is substituted with word lines, and the sub-word lines 22 and the main word line 29 are substituted with sub-bit lines and main bit lines, respectively. At this time, a control electrode may be coupled to the sub-bit lines.

FIGS. 6A to 6D are cross-sectional views illustrating a variable resistor that may be applied to a semiconductor memory device in accordance with an embodiment of the present invention.

Referring to FIG. 6A, a variable resistor may have a structure where a first electrode 61, a phase-change material layer 62 (for example, a material with phase-changeable properties), and a second electrode 63 are sequentially stacked.

The resistance value of the phase-change material layer 62 varies as the state of the phase-change material layer 62 is changed in response to an external stimulus, e.g., current or voltage. Here, the variable resistor may have a plurality of resistance values depending on the extent of the change of the phase-change material layer 62 into an amorphous state or crystal state. Also, the variable resistor may be formed to have a plurality of resistance values by serially coupling a plurality of structures where the first electrode 61, the phase-change material layer 62, and the second electrode 63 are stacked.

The phase-change material layer 62 may be formed of chalcogen compound. For example, the chalcogen compound for forming the phase-change material layer 62 may include: germanium-antimony-tellurium (Ge—Sb—Te), arsenic-antimony-tellurium (As—Sb—Te), tin-antimony-tellurium (Sn—Sb—Te), tin-indium-antimony-tellurium (Sn—In—Sb—Te), arsenic-germanium-antimony-tellurium (As—Ge—Sb—Te), 5A-group element-antimony-tellurium (5A-group element-Sb—Te), 6A-group element-antimony-tellurium (6A-group element-Sb—Te), 5A-group element-antimony-selenium (5A-group element-Sb—Se), and 6A-group element-antimony-selenium (6A-group element-Sb—Se). Here, the 5A-group element includes tantalium (Ta), niobium (Nb), and vanadium (V), and the 6A-group element includes tungsten (W), molybdenum (Mo), and chromium (Cr). The chalcogen compound (GST) that is prepared by mixing germanium-antimony-tellurium (Ge—Sb—Te) in a predetermined ratio is generally used to form the phase-change material layer 62.

Referring to FIG. 6B, the variable resistor may have a structure where a first electrode 71, a variable resistance layer 72, and a second electrode 73 are sequentially stacked.

As for the variable resistance layer 72, a perovskite-based material, a binary oxide including a transition metal oxide (TMO), or a PMC-based solid electrolyte material may be used. More specifically, the perovskite-based material may include strontium titanium oxide (SrTiO: STO) and praseodymium calcium manganese oxide (PrCaMnO: PCMO), and the binary oxide including a transition metal oxide (TMO) may include nickel (Ni) oxide, titanium (Ti) oxide, hafnium (Hf) oxide, zirconium (Zr) oxide, tungsten (W) oxide, and cobalt (Co) oxide.

Here, when the variable resistance layer 72 is formed of a transition metal oxide, the variable resistance layer 72 includes a plurality of oxygen vacancies in its inside, and the resistance value of the variable resistance layer 72 varies depending on whether conductive filaments are generated or not by re-arrangement of the oxygen vacancies due to an external stimulus, e.g., current or voltage. Here, the variable resistance layer 72 may have its resistance value varying depending on the conductive extent of the generated conductive filaments. Also, the variable resistor may be formed to have a plurality of resistance values by serially coupling a plurality of structures where the first electrode 71, the variable resistance layer 72, and the second electrode 73 are stacked.

Referring to FIG. 6C, a variable resistor may have a structure where a first electrode 81, a magnetic tunnel junction layer 86, and the second electrode 87 are sequentially stacked.

The magnetic tunnel junction layer 86 may be a stacked layer where a pinning layer 82, a pinned layer 83, a tunnel insulation layer 84, and a free layer 85 are stacked. Here, the magnetic tunnel junction layer 86 has a resistance value that varies based on the magnetization direction of the free layer 85, which changes in response to an external stimulus, e.g., magnetic field or spin transfer torque (STT). Here, the magnetic tunnel junction layer 86 may have a plurality of resistance values depending on the variation extent of the magnetization direction of the free layer 85. Also, the variable resistor may be formed to have a plurality of resistance values by serially coupling a plurality of structures where the first electrode 81, the magnetic tunnel junction layer 86, and the second electrode 87 are stacked.

The pinning layer 82 serves to fix the magnetization direction of the pinned layer 83, and it may be formed of an antiferromagnetic material. The antiferromagnetic material may include: iridium manganese (IrMn), platinum manganese (PtMn), manganese oxide (MnO), manganese sulfide (MnS), manganese telluride (MnTe), manganese difluoride (MnF₂), ferrous difluoride (FeF₂), ferrous dichloride (FeCl₂), ferrous oxide (FeO), cobalt dichloride (CoCl₂), cobalt oxide (CoO), nickel dichloride (NiCl₂), and nickel oxide (NiO).

The pinned layer 83 and the free layer 85 may be formed of a material having a ferromagnetic property. The ferromagnetic material may include iron (Fe), cobalt (Co), nickel (Ni), gadolinium (Gd), dysprosium (Dy), nickel iron (NiFe), cobalt iron (CoFe), manganese arsenide (MnAs), manganese bismuthide (MnBi), manganese antimonide (MnSb), chromium dioxide (CrO₂), manganese ferrite (MnOFe₂O₃), iron ferrite (FeOFe₂O₃), nickel ferrite (NiOFe₂O₃), copper ferrite (CuOFe₂O₃), magnesium ferrite (MgOFe₂O₃), europium oxide (EuO), and yttrium-iron-garnet (Y₃Fe₅O₁₂).

The tunnel insulation layer 84 serves as a tunneling barrier between the pinned layer 83 and the free layer 85, and the tunnel insulation layer 84 may be formed of magnesium oxide (MgO), aluminum oxide (Al₂O₃), silicon nitride (Si₃N₄), silicon oxynitride (SiON), silicon dioxide (SiO₂), hafnium dioxide (HfO₂), and zirconium dioxide (ZrO₂). Besides, the tunnel insulation layer 84 may be formed of any material having insulation characteristics.

Referring to FIG. 6D, the variable resistor may have a structure where a first electrode 91, a ferroelectric layer 92, and a second electrode 93 are sequentially stacked.

The ferroelectric layer 92 has spontaneous polarization properties, and the resistance value of the ferroelectric layer 92 varies by causing polarization inversion due to an external stimulus. Here, the ferroelectric layer 92 may have a plurality of resistance values depending on the variation extent of the spontaneous polarization. Also, the variable resistor may be formed to have a plurality of resistance values by serially coupling a structure where the first electrode 91, the ferroelectric layer 92, and the second electrode 93 are stacked. The ferroelectric layer 92 may be formed of strontium bismuth tantalite (SrBiTa: SBT), lead zirconium titanite (PbZrTi: PZT), or bismuth lanthanum titanite (BiLaTi: BLT).

The semiconductor memory device in accordance with an embodiment of the present invention may simultaneously decrease off-current of a diode while increasing on-current of the diode by including a control electrode. Therefore, the semiconductor memory device in accordance with an embodiment of the present invention may enhance on/off characteristics of the diode at the same time and have enhanced operation characteristics.

Also, since the semiconductor memory device in accordance with an embodiment of the present invention has a structure where a control electrode and a main word line are coupled, it does not require a device for controlling a bias voltage that is applied to the control electrode. Therefore, the integration degree of the semiconductor memory device may be increased.

While the present invention has been described with respect to the specific embodiments, it will be apparent to those skilled in the art that various changes and modifications may be made without departing from the spirit and scope of the invention as defined in the following claims.

What is claimed is:

1. A switching device comprising:
a diode including a first conductive layer and a second conductive layer stacked therein, wherein the first conductive layer and the second conductive layer have complementary conductive types to each other;
a control electrode surrounding the first conductive layer; and
an insulation layer disposed between the first conductive layer and the control electrode.

2. The switching device of claim 1, wherein the control electrode surrounds a part or an entire of a side of the first conductive layer.

3. The switching device of claim 1, wherein the same bias voltage is applied to the first conductive layer and the control electrode.

4. The switching device of claim 1, wherein the diode comprises a PN diode.

5. The switching device of claim 4, wherein the PN diode is formed of silicon or an oxide as a compound semiconductor.

6. A semiconductor memory device, comprising:
a plurality of word lines;
a plurality of bit lines crossing over the word lines; and
memory cells disposed at intersections of the word lines and the bit lines and including a switching device and a variable resistor that are serially coupled,
wherein the switching device comprises:
a first conductive layer;
a second conductive layer, wherein the first conductive layer and the second conductive layer are sequentially stacked and have complementary conductive types to each other; and
a control electrode surrounding the first conductive layer.

7. The semiconductor memory device of claim 6, wherein the control electrode is electrically connected to the word lines.

8. The semiconductor memory device of claim 7, wherein the word lines and the first conductive layer are electrically connected to each other.

9. The semiconductor memory device of claim 8, wherein the word lines region includes a conductive type the same as a conductive type of the first conductive layer.

10. The semiconductor memory device of claim 6, wherein the control electrode is formed as a line pattern stretched in the same direction as the word lines.

11. The semiconductor memory device of claim 6, wherein the control electrode and the word lines are overlapped.

12. The semiconductor memory device of claim 6, wherein the control electrode surrounds a part or an entire of a side of the first conductive layer.

13. The semiconductor memory device of claim 6, wherein the first and second conductive layers constitute a PN diode.

14. The semiconductor memory device of claim 6, wherein the variable resistor comprises one selected from the group consisting of a phase-change material layer, a variable resistance layer, a magnetic tunnel junction layer, and a ferroelectric layer.

15. A semiconductor memory device, comprising:
a plurality of sub-word lines formed over a substrate;
a first conductive layer and a second conductive layer sequentially stacked over the sub-word lines, wherein the first conductive layer and the second conductive layer have complementary conductive type to each other;
a control line formed over the sub-word lines and surrounding the first conductive layer;
an insulation layer interposed between the first conductive layer and the control line;
a variable resistor formed over the second conductive layer; and
a plurality of bit lines formed over the variable resistor and crossing over the sub-word lines.

16. The semiconductor memory device of claim 15, further comprising:
main word lines crossing over the bit lines and electrically connected to the sub-word lines and the control line.

17. The semiconductor memory device of claim 16, wherein the sub-word lines and the control line are disposed for a mat of the semiconductor memory device, and the main word lines are disposed for a bank of the semiconductor memory device.

18. The semiconductor memory device of claim 16, wherein the main word lines, the sub-word lines, and the control line are stretched in the same direction and overlapped.

19. The semiconductor memory device of claim 15, wherein the sub-word lines comprise an impurity region formed over the substrate.

20. The semiconductor memory device of claim 19, wherein a conductive type of the impurity region is the same as a conductive type of the first conductive layer.

21. The semiconductor memory device of claim 19, wherein an impurity doping concentration of the impurity region is higher than an impurity doping concentration of the first conductive layer.

22. The semiconductor memory device of claim 15, wherein the first and second conductive layers constitute a diode and the semiconductor memory device comprises a plurality of PN diodes as the diode.

23. The semiconductor memory device of claim 15, wherein the control line surrounds a part or an entire of a side of the first conductive layer.

24. The semiconductor memory device of claim 15, wherein the variable resistor comprises one selected from the group consisting of a phase-change material layer, a variable resistance layer, a magnetic tunnel junction layer, and a ferroelectric layer.
